(19) United States
(12) Patent Application Publication
(10) Pub. No.: US 2009/0260671 A1
(43) Pub. Date: Oct. 22, 2009

(54) SYSTEMS AND METHODS OF PARALLEL INTERCONNECTION OF PHOTOVOLTAIC MODULES

(75) Inventors: Roger Thomas Green, St. Charles, MO (US); John Kenneth Christiansen, Toledo, OH (US); Ricky C. Powell, Ypsilanti, MI (US); Michael David Ross, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/334,028

(22) Filed: Dec. 12, 2008

Related U.S. Application Data
(60) Provisional application No. 61/013,418, filed on Dec. 13, 2007.

(51) Int. Cl. H01L 31/042; H01L 31/18

(52) U.S. Cl. 136/244; 438/80; 257/E21.085

(57) ABSTRACT

A photovoltaic system includes a first submodule and a second submodule connected in parallel.

### CLAIM FOR PRIORITY

This application claims priority under 35 U.S.C. §119(e) to Provisional U.S. Patent Application Ser. No. 61/013,418 filed on Dec. 13, 2007, which is hereby incorporated by reference.

### TECHNICAL FIELD

This invention relates to photovoltaic devices.

### BACKGROUND

Photovoltaic modules are typically used in arrays of interconnected submodules. Each submodule is comprised of individual solar cells, typically connected in series. Thin film photovoltaic modules are formed by the deposition of multiple semiconductor or organic thin films on rigid or flexible substrates or superstrates. Electrical contact to the solar cell material on the substrate side is provided by an electrically conductive substrate material or an additional electrically conductive layer between the solar cell material and the substrate such as a transparent conductive layer.

### SUMMARY

A photovoltaic system can include a transparent conductive layer on a substrate, and a first submodule and a second submodule connected in parallel and contacting the transparent conductive layer through a shared cell, the first submodule having an electrical contact region including a first trench pattern, wherein the first trench pattern is a pattern of photovoltaic cells connected in series and a last cell in the series is the shared cell. The second submodule can have an electrical contact region including a second trench pattern, wherein the second trench pattern is a mirror image of the first trench pattern, the mirror image having symmetry about the shared cell.

In some circumstances, the system can include a trench pattern that includes one or more trench depths. A trench pattern can include a trench having a depth that extends substantially through one layer. A trench pattern can include a trench having a depth that extends substantially through two layers. A trench pattern can include a trench having a depth that extends substantially through three layers.

A trench pattern can be formed by laser ablation, laser scribing, wet-chemical etching, or dry etching. A trench pattern can include constant spacing between scribes.

In some circumstances, a photovoltaic system can include a metal layer over a shared cell. A shared cell can be flanked by two electrical contacts between the transparent conductive layer and a metal layer. A shared cell can be in a center between the first and second submodules.

In some circumstances, a photovoltaic cell can include an insulator. The insulator can be a dielectric material, atmosphere or vacuum. The insulator can be in a constant position among photovoltaic cells connected in series.

A photovoltaic cell can include a first semiconductor material. In some circumstances, a photovoltaic cell can include a second semiconductor material over the first semiconductor material. The first semiconductor material can be a CdS. The second semiconductor material can be a CdTe. The substrate can be glass.

In some circumstances, a photovoltaic system can include a first submodule, which includes greater than 20 cells. The first submodule can include greater than 40 cells. The first submodule can include greater than 80 cells.

A method of manufacturing a system can include providing a transparent conductive layer on a substrate, contacting a first submodule and a second submodule with the transparent conductive layer through a shared cell, the first submodule and second submodule being connected in parallel, the first submodule having an electrical contact region including a first trench pattern, wherein the first trench pattern is a pattern of photovoltaic cells connected in series and a last cell in the series is the shared cell.

A photovoltaic structure can include a semiconductor layer on a transparent conductive layer, the semiconductor layer having a scribe pattern that forms a cell, a metal layer over the cell, and two electrical contacts between the transparent conductive layer and the metal layer. A first electrical contact can be positioned on one side of the cell, and a second electrical contact can be positioned on an opposite side of the cell. The first or second electrical contact can have a length that spans the length of a semiconductor layer and an end that contacts the transparent conductive layer. Alternatively, both first and second electrical contacts can have the length of a scribe that spans the length of a semiconductor layer and an end that contacts the transparent conductive layer.

A method of forming a photovoltaic structure can include depositing a semiconductor layer over a transparent conductive layer, scribing the semiconductor layer to form a cell, the cell comprising a semiconductor material shared by two parallel connected submodules, and metallizing the cell.

A method of forming a photovoltaic structure can include depositing a semiconductor layer over a transparent conductive layer, scribing a semiconductor layer to form a cell, placing a metal layer over the cell and forming two electrical contacts between the transparent conductive layer and the metal layer.

The details of one or more embodiments are set forth in the accompanying drawings and the description below. Other features, objects, and advantages will be apparent from the description and drawings, and from the claims.

### DESCRIPTION OF DRAWINGS

FIG. 1 is a schematic of a photovoltaic system.

FIG. 2 is a schematic of a photovoltaic structure.

### DETAILED DESCRIPTION

In general, a photovoltaic system is comprised of several modules. A module is comprised of two or more submodules connected in parallel. A submodule is comprised of series-connected individual cells. Photovoltaic modules can be used in arrays of many, interconnected modules.

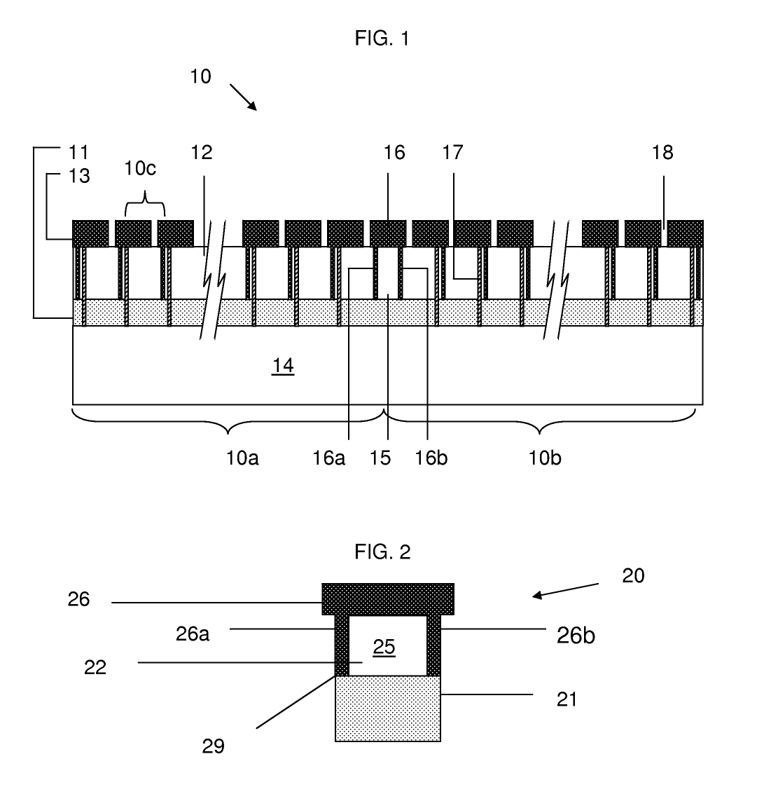

Referring to FIG. 1, a photovoltaic system can include a photovoltaic module 10, which is formed by a parallel connection of first submodule 10a and a second submodule 10b. Each submodule includes individual photovoltaic cells 10c, typically connected in series. A photovoltaic system can include a transparent conductive layer 11 on a substrate 14, and a first submodule and a second submodule connected in parallel and contacting the transparent conductive layer through a shared cell 15. A submodule can include a semiconductor layer 12 over a substrate. A photovoltaic cell can be scribed to form a trench 18. A trench pattern can be formed by a plurality of scribes. A trench pattern can include constant spacing between scribes. A system can include a trench pattern that includes one or more trench depths. A trench pattern can include a trench having a depth that extends substantially through one layer. A trench pattern can include a trench having a depth that extends substantially through two layers. A trench pattern can include a trench having a depth that extends substantially through three layers. Trench patterns can be formed by laser ablation, laser scribing, wet-chemical etching, or dry etching techniques, for example.

With continuing reference to FIG. 1, the first submodule can have an electrical contact region including a first trench pattern, wherein the first trench pattern is a pattern of photovoltaic cells 10c connected in series and a last cell in the series is the shared cell 15. The second submodule can have an electrical contact region including a second trench pattern, wherein the second trench pattern is a mirror image of the first trench pattern, the mirror image having symmetry about the shared cell. A photovoltaic cell can include an insulator 17. The insulator can be a dielectric material, atmosphere or vacuum. The insulator can be in a constant position among photovoltaic cells connected in series. The insulator can penetrate the semiconductor material, the transparent conductive layer, or both. The insulator can have a length that spans the length of a semiconductor material and a transparent conductive layer combined. A photovoltaic system can include a metal layer 13. A metal layer can have a region 16 over a shared cell. A shared cell can be flanked by two electrical contacts 16a and 16b between the transparent conductive layer and a metal layer. A shared cell can be in a center between the first and second submodules.

Referring to FIG. 2, a photovoltaic structure 20 can include a semiconductor layer 22 on a transparent conductive layer 21, the semiconductor layer having a scribe pattern that forms a cell 25, a metal layer 26 over the cell, and two electrical contacts 26a and 26b between the transparent conductive layer and the metal layer. A first electrical contact can be positioned on one side of the cell, and a second electrical contact can be positioned on an opposite side of the cell. The first or second electrical contact can have a length that spans the length of a semiconductor layer and an end that contacts the transparent conductive layer. The first or second electrical contact can penetrate through a semiconductor layer and contact a transparent conductive layer. The first or second electrical contact can have the length of a scribe that spans the length of a semiconductor layer deposited on a transparent conductive layer, such that one end 29 of the electrical contact is on the transparent conductive layer. Alternatively, the first and second electrical contacts can each have the length of a scribe that spans the length of a semiconductor layer deposited on a transparent conductive layer, and an end that contacts the transparent conductive layer.

According to other methods, submodules have been connected in parallel via electrical bus lines such as metal tape with a pressure sensitive adhesive that allows electrical contact between the tape and the underlying material and/or soldered metal conductors, such as a wire or ribbon conductor. Electrical contact to the positive and negative polarity electrical connections of the module was conventionally made by soldering or other similar technique to an electrical bus network that connects the submodules within the module.

With other systems, each submodule had both a negative and positive contact, and the last cell in a series was used to provide electrical contact to the electrically conductive substrate or transparent conductive layer. This last cell in the series that provides the contact is electrically shorted, and accordingly, does not produce power and consequently reduces the overall efficiency of the module. Further, the connection of the submodules by electrical tape, soldering wires, solder pads, conductive paint, silk screening, bus tape, or additional insulating and metal depositions, increases the cost, time, and complexity of manufacturing. This also leads to reduced reliability of photovoltaic modules.

The systems and structures as shown in FIG. 1 and FIG. 2 made by the methods described herein can reduce or otherwise obviate the need for each submodule to have its own individual contact to a transparent conductive layer or electrically conductive substrate. This results in better module efficiency, lower cost and greater reliability than that obtained with the prior art. The parallel interconnection of the two submodules as shown in FIG. 1 can be obtained by allowing both of the submodules to share the contact to a transparent conductive layer on a substrate. A first submodule and a second submodule can be connected in parallel and contacting the transparent conductive layer through a shared cell. The first submodule can have an electrical contact region including a first trench pattern, wherein the first trench pattern is a pattern of photovoltaic cells connected in series, and a last cell in the series is the shared cell. The second submodule can have an electrical contact region including a second trench pattern, wherein the second trench pattern is a mirror image of the first trench pattern, the mirror image having symmetry about the shared cell. This structure can be applied to any and number of submodules, N (where N is a natural number greater than 1). The output voltage of the will decrease proportionally with N. This provides the ability to control the output voltage of the modules to optimally meet a solar array's system requirements.

The advantages of structure include reduced balance of system (BOS) costs, reduced processing time, reduced complexity, increased module efficiency, and greater reliability. This structure allows lower voltage per module without lowering the output power per module. The lower voltage per module allows more modules per series-connected module string in the solar array. This reduces the number of series-connected module strings per solar array, which provides a significant cost reduction. Increased efficiency of modules also results from a smaller active area being lost to provide electrical contact to submodules. Finally, because the shared contact is created concurrently with the series connection of the individual cells within the submodules, the contact is formed as the series connection between individual cells is made. This eliminates the complexity, cost, and potential reliability issues associated interconnecting submodules with an additional electrical bus lines, for example.

The total output current of the module is the sum of the currents of each of the submodules. Thus, the optimum design of sub-modules within a module is determined by system requirements. In general, photovoltaic modules are formed by the deposition of multiple semiconductor or organic thin films on rigid or flexible substrates or superstrates. The term superstrate is generally used if the light incident on a module passes through the transparent substrate used for semiconductor or organic film deposition. Electrical contact to the solar cell material on the substrate side can be provided by an electrically conductive substrate material or an electrically conductive layer between the solar cell material and the substrate such as a transparent conductive layer or a transparent conductive oxide (TCO). For superstrates, electrical contact on the substrate side of the solar cell material can be provided by patterned metal layers and/or a TCO, for example.

The deposition of semiconductor material can form a semiconductor layer, which can be processed to improve the electrical and optical characteristics of the layer, and then scribed into individual solar cells. Scribing can form various levels of trenches. Scribing can be performed by, laser ablation, laser scribing, wet-chemical etching, or dry etching techniques, for example.

A photovoltaic cell can include a second semiconductor material over the first semiconductor material. The first semiconductor material can be a CdS. The second semiconductor material can be a CdTe. The substrate can be glass. A photovoltaic cell can be part of a submodule, which includes greater than 50 cells. The submodule can also include greater than 80 cells. The submodule can also include greater than 100 cells.

A method of manufacturing a system can include providing a transparent conductive layer on a substrate, contacting a first submodule and a second submodule with the transparent conductive layer through a shared cell, the first submodule and second submodule being connected in parallel, the first submodule having an electrical contact region including a first trench pattern, wherein the first trench pattern is a pattern of photovoltaic cells connected in series and a last cell in the series is the shared cell.

A method of forming a photovoltaic structure can include depositing a semiconductor layer over a transparent conductive layer, scribing the semiconductor layer to form a cell, the cell comprising a semiconductor material shared by two parallel connected submodules, and metallizing the cell.

A method of forming a photovoltaic structure can include depositing a semiconductor layer over a transparent conductive layer, scribing a semiconductor layer to form a cell, placing a metal layer over the cell and forming two electrical contacts between the transparent conductive layer and the metal layer.

In this system, a photovoltaic cell can be constructed of a series of layers of semiconductor materials deposited on a glass substrate. In an example of a common photovoltaic cell, the multiple layers can include: a bottom layer that is a transparent conductive layer, a window layer, an absorber layer, and a top layer. The top layer can be a metal layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. Additional layers can be added using other techniques such as sputtering. Electrical conductors can be connected to the top and the bottom layers respectively to collect the electrical energy produced when solar energy is incident onto the absorber layer. A top substrate layer can be placed on top of the top layer to form a sandwich and complete the photovoltaic device.

The bottom layer can be a transparent conductive layer, and can be for example a transparent conductive oxide such as zinc oxide, zinc oxide doped with aluminum, tin oxide or tin oxide doped with fluorine. Sputtered aluminum doped zinc oxide has good electrical and optical properties, but at temperatures greater than 500° C., aluminum doped zinc oxide can exhibit chemical instability. In addition, at processing temperatures greater than 500° C., oxygen and other reactive elements can diffuse into the transparent conductive oxide, disrupting its electrical properties.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures, compounds or alloys thereof. An example of a window layer and absorbing layer is a layer of CdS coated by a layer of CdTe.

A metal layer can be deposited as an electrical contact to a semiconductor layer for solar device operation, as taught, for example, in U.S. Patent Application Ser. No. 60/868,023, which is hereby incorporated by reference in its entirety. A metal layer can be a composite layer comprised of metal layers, such as a Cr/Al/Cr metal stack. The metal layers in a composite layer can be metals that have a thermal expansion coefficient between the semiconductor layer and a first metal layer. Metal adhesion is impacted by intrinsic stress, which is a function of deposition variables. Metal adhesion is also impacted by extrinsic stresses such as post-deposition thermal treatment in which case dissimilarity in thermal expansion coefficients may contribute to reduced adhesion. A proper sequential arrangement of metals, such as chromium, nickel, and aluminum, can provide a gradient in thermal expansion of the metal stack thereby minimizing loss of adhesion during thermal processing.

Additional metal layers can be added in order to provide a gradient of thermal expansion coefficients thereby minimizing de-lamination during heat treatment. Adhesion has been shown to be improved when thermal expansion coefficients of selected materials were more closely matched.

Additional layers, such as a protective layer of material with a high chemical stability, or a capping layer can also be provided. Capping layers are described, for example, in U.S. Patent Publication 20050257824, which is incorporated by reference herein.

A method of making a photovoltaic cell can include placing a semiconductor layer on a substrate and depositing a metal layer in contact with a semiconductor layer to metallize a photovoltaic cell. In certain circumstances a metal layer can be a chromium-containing layer. In other circumstances, metal layers can be deposited sequentially to form a metal stack. For example, a first metal layer can be a chromium-containing layer, a third metal layer can be an aluminum-containing layer, and second layer between the first and third metal layers can be a nickel-containing layer. In another embodiment, a photovoltaic device can further comprise a fourth layer, wherein the fourth layer is an intermediate layer between the second metal layer and the third metal layer. The intermediate layer can be a nickel-containing layer. A metal layer can also include tungsten, molybdenum, iridium, tantalum, titanium, neodymium, palladium, lead, iron, silver, or nickel.

In certain circumstances, a capping layer can be deposited in addition to a tin oxide protective layer. A capping layer can be positioned between the transparent conductive layer and the window layer. The capping layer can be positioned between the protective layer and the window layer. The capping layer can be positioned between the transparent conductive layer and the protective layer. The capping layer can serve as a buffer layer, which can allow a thinner window layer to be used. For example, when using a capping layer and a protective layer, the first semiconductor layer can be thinner than in the absence of the buffer layer. For example, the first semiconductor layer can have a thickness of greater than about 10 nm and less than about 600 nm. For example, the first semiconductor layer can have a thickness greater than 20 nm, greater than 50 nm, greater than 100 nm, or greater than 200 nm and less than 400 nm, less than 300 nm, less than 250 nm, or less than 150 nm.

The first semiconductor layer can serve as a window layer for the second semiconductor layer. By being thinner, the first semiconductor layer allows greater penetration of the shorter wavelengths of the incident light to the second semiconductor layer. The first semiconductor layer can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures, compounds or alloys thereof. It can be a binary semiconductor, for example it can be CdS. The second semiconductor layer can be deposited onto the first semiconductor layer. The second semiconductor can serve as an absorber layer for the incident light when the first semiconductor layer is serving as a window layer. Similar to the first semiconductor layer, the second semiconductor layer can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, A1P, AlAs, AlSb, GaN, GaP, GaAs, GaSb, InN, InP, InAs, InSb, TlN, TlP, TlAs, TlSb, or mixtures, compounds or alloys thereof.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic devices can include a conveyor, for example a roll conveyor with rollers. Other types of systems with or without conveyors can also be used. A conveyor can transport substrates into a series of one or more deposition stations for depositing layers of material on the exposed surface of the substrate. The deposition chamber can be heated to reach a processing temperature of not less than about 450° C. and not more than about 700° C., for example the temperature can range from 450-550°, 550-650°, 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations each station with its own vapor distributor and supply. The distributor can be in the form of a spray nozzle with varying nozzle geometries to facilitate uniform distribution of the vapor supply.

Devices including protective layers can be fabricated using soda lime float glass as a substrate. A film of aluminum-doped ZnO can be commercially deposited by sputtering or by atmospheric pressure chemical vapor deposition (APCVD). Other doped transparent conducting oxides, such as a tin oxide can also be deposited as a film. Conductivity and transparency of this layer suit it to serving as the front contact layer for the photovoltaic device.

A second layer of a transparent conducting oxide, such as tin oxide, or tin oxide with zinc can be deposited. This layer is transparent, but conductivity of this layer is significantly lower than an aluminum-doped ZnO layer or a fluorine doped SnO₂ layer, for example. This second layer can also serve as a buffer layer, since it can be used to prevent shunting between the transparent contact and other critical layers of the device. The protective layers were deposited in house by sputtering onto aluminum-doped ZnO layers during device fabrication for these experiments. The protective layers were deposited at room temperature. A silicon dioxide capping layer can be deposited over a transparent conducting oxide using electron-beam evaporation.

Devices can be finished with appropriate back contact methods known to create devices from CdTe PV materials. Testing for results of these devices was performed at initial efficiency, and after accelerated stress testing using I/V measurements on a solar simulator. Testing for impact of chemical breakdown in the front contact and protective layers was done with spectrophotometer reflectance measurements, conductivity (sheet resistance) measurements.

A number of embodiments have been described. Nevertheless, it will be understood that various modifications may be made without departing from the spirit and scope of the invention. For example, the semiconductor layers can include a variety of other materials, as can the materials used for the buffer layer and the protective layer. In another example, additional electrical isolation from cell to cell can be achieved by employing additional isolation trenches. Accordingly, other embodiments are within the scope of the following claims.

What is claimed is:

1. A photovoltaic system comprising:
a transparent conductive layer on a substrate; and
a first submodule and a second submodule connected in parallel and contacting the transparent conductive layer through a shared cell, the first submodule having an electrical contact region including a first trench pattern, wherein the first trench pattern is a pattern of photovoltaic cells connected in series and a last cell in the series is the shared cell.

2. The system of claim 1, wherein the second submodule has an electrical contact region including a second trench pattern, wherein the second trench pattern is a mirror image of the first trench pattern, the mirror image having symmetry about the shared cell.

3. The system of claim 1, wherein the trench pattern includes a trench having a depth that extends substantially through one layer.

4. The system of claim 1, wherein the trench pattern includes a trench having a depth that extends substantially through two layers.

5. The system of claim 1, wherein the trench pattern includes a trench having a depth that extends substantially through three layers

6. The system of claim 1, wherein the trench pattern is formed by laser ablation, laser scribing, wet-chemical etching, or dry etching.

7. The system of claim 1, wherein the trench pattern includes constant spacing between scribes.

8. The system of claim 1, further comprising a metal layer over the shared cell.

9. The system of claim 8, wherein the shared cell is flanked by two electrical contacts between the transparent conductive layer and a metal layer.

10. The system of claim 1, wherein the shared cell is in a center between the first and second submodules.

11. The system of claim 1, wherein a photovoltaic cell includes an insulator.

12. The system of claim 11, wherein the insulator is a dielectric material, atmosphere or vacuum.

13. The system of claim 11, wherein the insulator is in a constant position among photovoltaic cells connected in series.

14. The system of claim 1, wherein a photovoltaic cell includes a first semiconductor material.

15. The system of claim 14, further comprising a second semiconductor material over the first semiconductor material.

16. The system of claim 14, wherein the first semiconductor material is a CdS.

17. The system of claim 15, wherein the second semiconductor material is a CdTe.

18. The system of claim 1, wherein the substrate is glass.

19. The system of claim 1, wherein the first submodule includes greater than 20 cells.

20. The system of claim 1, wherein the first submodule includes greater than 40 cells.

21. The system of claim 1, wherein the first submodule includes greater than 80 cells.

22. A method of manufacturing a system including:
providing a transparent conductive layer on a substrate;
contacting a first submodule and a second submodule with the transparent conductive layer through a shared cell, the first submodule and second submodule being connected in parallel, the first submodule having an electrical contact region including a first trench pattern, wherein the first trench pattern is a pattern of photovoltaic cells connected in series and a last cell in the series is the shared cell.

23. The method of claim 22, wherein the second submodule has an electrical contact region including a second trench pattern, wherein the second trench pattern is a mirror image of the first trench pattern, the mirror image having symmetry about the shared cell.

24. The method of claim 22, wherein the first trench pattern includes one or more trench levels.

25. The method of claim 22, wherein the second submodule has a second trench pattern that includes one or more trench levels.

26. The method of claim 22, wherein the trench pattern is formed by laser ablation, laser scribing, wet-chemical etching, or dry etching.

27. The method of claim 22, wherein the trench pattern includes constant spacing between scribes.

28. The method of claim 22, further comprising positioning a metal layer over the shared cell.

29. The method of claim 28, wherein the shared cell is flanked by two electrical contacts between the transparent conductive layer and a metal layer.

30. The method of claim 22, wherein the shared cell is in a center between the first and second submodules.

31. The method of claim 22, wherein the shared cell includes a first semiconductor material.

32. The method of claim 31, further comprising depositing a second semiconductor material over the first semiconductor material.

33. A photovoltaic structure including:
a semiconductor layer on a transparent conductive layer, the semiconductor layer having a scribe pattern that forms a cell;
a metal layer over the cell; and
a first and second electrical contact between the transparent conductive layer and the metal layer.

34. The structure of claim 33, wherein the cell is a shared cell between a first and second submodule, each having an electrical contact region including a first trench pattern and a second trench pattern, respectively.

35. The structure of claim 33, wherein the first electrical contact is positioned on one side of the cell, and the second electrical contact is positioned on an opposite side of the cell.

36. The structure of claim 33, wherein first or second electrical contact has a length that spans the length of a semiconductor layer and an end that contacts the transparent conductive layer.

37. The structure of claim 33, wherein first and second electrical contact each have a length that spans the length of a semiconductor layer and an end that contacts the transparent conductive layer.

38. The structure of claim 34, wherein the trench pattern includes constant spacing between scribes.

39. The structure of claim 34, further comprising a metal layer over the shared cell.

40. The structure of claim 39, wherein the shared cell is flanked by two electrical contacts between the transparent conductive layer and a metal layer.

41. The structure of claim 34, wherein the shared cell is in a center between the first and second submodules.

42. The structure of claim 34, wherein the cell includes an insulator.

43. The structure of claim 42, wherein the insulator is a dielectric material, atmosphere or vacuum.

44. The structure of claim 42, wherein the insulator is in a constant position among photovoltaic cells connected in series.

45. The structure of claim 42, wherein the cell includes a first semiconductor material.

46. The structure of claim 45, further comprising a second semiconductor material over the first semiconductor material.

47. The system of claim 45, wherein the first semiconductor material is a CdS.

48. The system of claim 46, wherein the second semiconductor material is a CdTe.

49. A method of forming a photovoltaic structure including:
depositing a semiconductor layer over a transparent conductive layer;
scribing the semiconductor layer to form a cell, the cell comprising a semiconductor material shared by two parallel connected submodules; and
metallizing the cell.

50. The method of claim 49, wherein the two submodules includes a first submodule having an electrical contact region including first trench pattern and a second submodule having an electrical contact region including a second trench pattern, wherein the second trench pattern is a mirror image of the first trench pattern, the mirror image having a symmetry about the shared cell.

51. The method of claim 50, wherein the first trench pattern includes one or more trench levels.

52. The method of claim 50, wherein the second submodule has a second trench pattern that includes one or more trench levels.

53. The method of claim 50, wherein the trench pattern is formed by laser ablation, laser scribing, wet-chemical etching, or dry etching.

54. The method of claim 50, wherein the trench pattern includes constant spacing between scribes.

55. The method of claim 50, wherein metallizing the cell includes positioning a metal layer over the shared cell.

56. The method of claim 55, wherein the shared cell is flanked by two electrical contacts between the transparent conductive layer and a metal layer.

57. The method of claim 55, wherein the shared cell is in a center between the first and second submodules.

58. The method of claim 55, wherein the shared cell includes a first semiconductor material.

59. The method of claim 58, further comprising depositing a second semiconductor material over the first semiconductor material.

60. A method of forming a photovoltaic structure including:
depositing a semiconductor layer over a transparent conductive layer;
scribing a semiconductor layer to form a cell;
placing a metal layer over the cell; and
forming two electrical contacts between the transparent conductive layer and the metal layer.

61. The method of claim 60, wherein the cell is a shared cell between a first submodule having an electrical contact region including first trench pattern and a second submodule having an electrical contact region including a second trench pattern, wherein the second trench pattern is a mirror image of the first trench pattern, the mirror image having a symmetry about the shared cell.

62. The method of claim 61, wherein the first trench pattern includes one or more trench levels.

63. The method of claim 61, wherein the second submodule has a second trench pattern that includes one or more trench levels.

64. The method of claim 61, wherein the trench pattern is formed by laser ablation, laser scribing, wet-chemical etching, or dry etching.

65. The method of claim 61, wherein the trench pattern includes constant spacing between scribes.

66. The method of claim 61, wherein the shared cell is flanked by two electrical contacts between the transparent conductive layer and a metal layer.

67. The method of claim 61, wherein the shared cell is in a center between the first and second submodules.

68. The method of claim 61, wherein the shared cell includes a first semiconductor material.

69. The method of claim 61, further comprising depositing a second semiconductor material over the first semiconductor material.
